(19) United States
(12) Patent Application Publication
(10) Pub. No.: US 2025/0348423 A1
(43) Pub. Date: Nov. 13, 2025

(54) MEMORY DEVICES, OPERATION METHODS THEREOF, AND MEMORY SYSTEMS

(71) Applicant: Yangtze Memory Technologies Co., Ltd., Wuhan (CN)

(72) Inventors: Yongxiang Ma, Wuhan (CN); Yahai Liu, Wuhan (CN); Weihua Shi, Wuhan (CN); Wei Huang, Wuhan (CN); Weijun Wan, Wuhan (CN); Qianru Li, Wuhan (CN)

(21) Appl. No.: 18/814,050

(22) Filed: Aug. 23, 2024

(30) Foreign Application Priority Data
May 8, 2024 (CN) 202410565172.7

(51) Int. Cl. G06F 12/02

(52) U.S. Cl. CPC G06F 12/0223

(57) ABSTRACT

Examples of the present disclosure disclose a memory device and an operation method thereof and a memory system. The memory device comprises a memory cell array and a peripheral circuit coupled with the memory cell array. The memory cell array includes at least one first memory block and a plurality of second memory blocks, and part of the plurality of second memory blocks are configured as sampling memory blocks; and the peripheral circuit is configured to: perform an erase operation on the sampling memory block; and record an erase count of the sampling memory block in the first memory block.

### TECHNICAL FIELD

This application claims priority to and the benefit of Chinese Patent Application 202410565172.7, filed on May 8, 2024, which is hereby incorporated by reference in its entirety.

### TECHNICAL FIELD

Examples of the present disclosure relate to a semiconductor technology, and particularly to, but not limited to, a memory devices, operation methods of same, and memory systems.

### BACKGROUND

With the rapid development of information technology, memory technology is also witnessing continuous breakthroughs and innovations. A memory is a vital part of a computer system and is responsible for storage and reading of data, which directly affects the performance and user experience of a computer. In the past decades, memories have undergone many important technical breakthroughs and innovations.

### BRIEF DESCRIPTION OF THE DRAWINGS

In the drawings, like reference numerals may describe like components in different views. Like reference numerals having different letter suffixes may represent different examples of like components. The drawings generally illustrate the various examples discussed herein by way of examples rather than limitation.

FIG. 1A is a schematic structural diagram of a memory system provided by examples of the present disclosure.

FIG. 1B is a schematic structural diagram of a memory card provided by examples of the present disclosure.

FIG. 1C is a schematic structural diagram of a Solid State Disk (SSD) provided by examples of the present disclosure.

FIG. 1D and FIG. 1E are schematic structural diagrams of a memory device comprising a memory cell array and a peripheral circuit provided by examples of the present disclosure.

FIG. 1F is a schematic structural diagram of a memory cell array comprising a plurality of second memory blocks and at least one first memory block provided by examples of the present disclosure.

FIG. 2 is a schematic structural diagram of a memory cell array provided by examples of the present disclosure.

FIG. 3 is a comparison table between a total erase count and a preset erase count provided by examples of the present disclosure.

FIG. 4 is a flow diagram 1 of an operation method of a memory device provided by examples of the present disclosure.

FIG. 5 is a flow diagram 2 of an operation method of a memory device provided by examples of the present disclosure.

FIG. 6 is a schematic structural diagram of a memory system provided by examples of the present disclosure.

### DETAILED DESCRIPTION

Memories are still facing numerous challenges. How to continuously improve the performance of a memory becomes an urgent problem to be resolved.

For ease of understanding the present disclosure, the present disclosure will be described in detail below with reference to the related drawings. Preferable examples of the present disclosure are given in the drawings. However, the present disclosure may be implemented in many different forms, and is not limited to the examples described herein. Instead, the purpose of providing these examples is to make the disclosure of the present disclosure more thorough and comprehensive.

Unless otherwise defined, all technical and scientific terms used herein have the same meanings as those generally understood by those skilled in the technical field of the present disclosure. The terms used in the specification of the present disclosure herein are only for the purpose of describing specific examples, and are not intended to limit the present disclosure. The term “at least one of” used herein comprise combinations of any and all of one or more listed associated items.

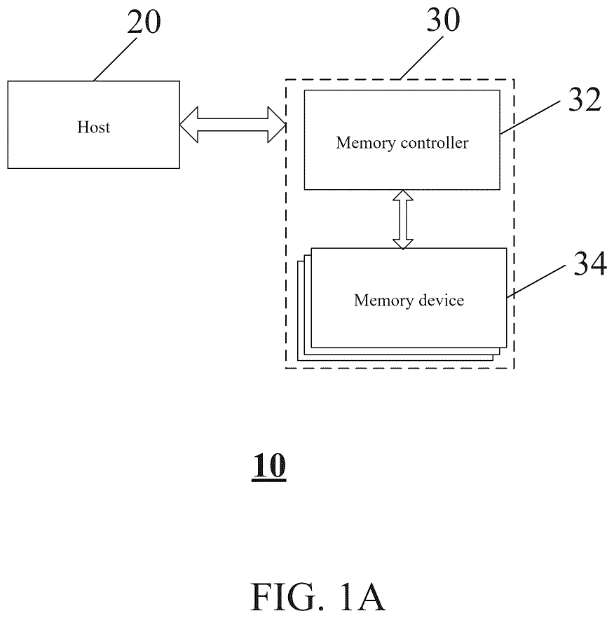

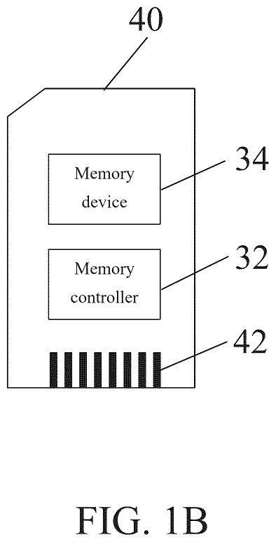

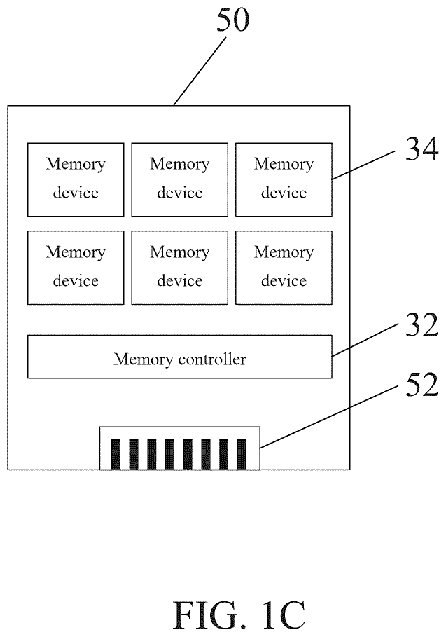

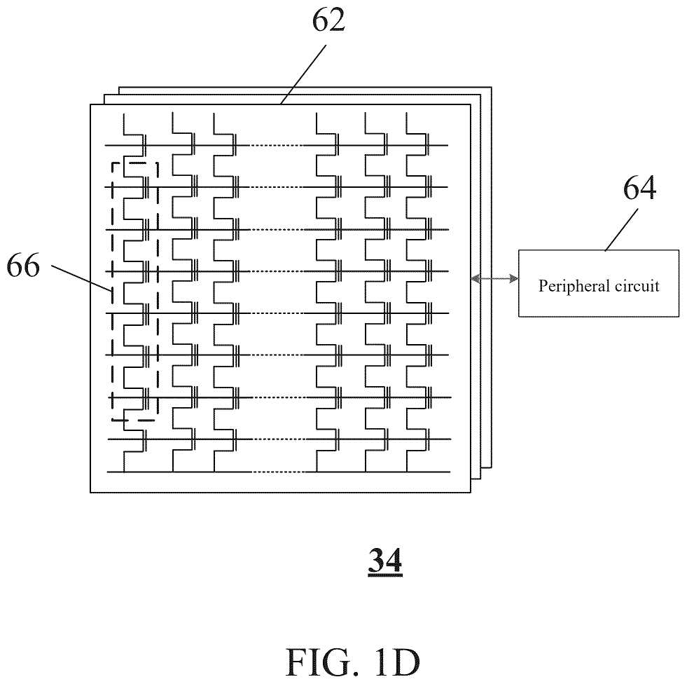

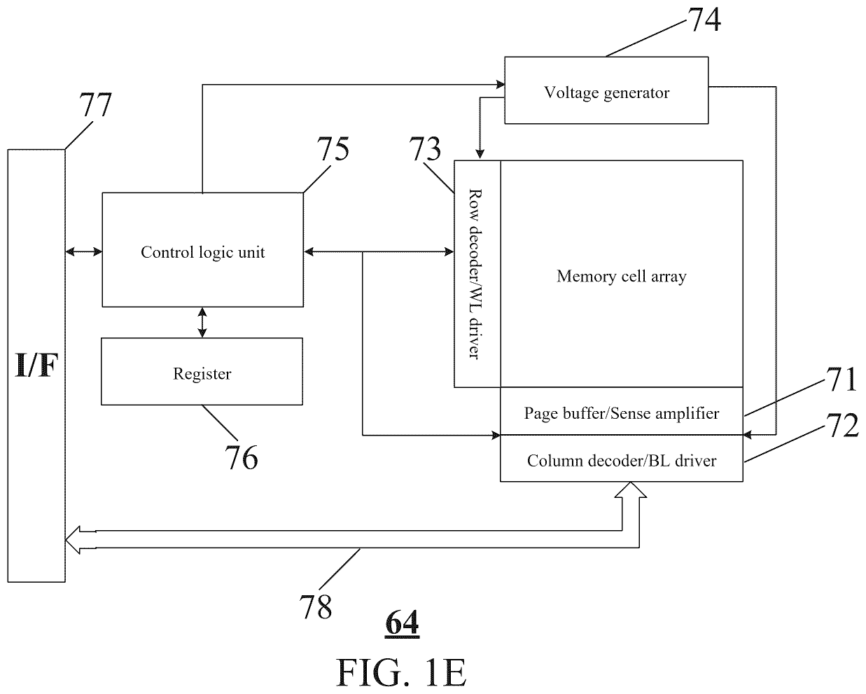

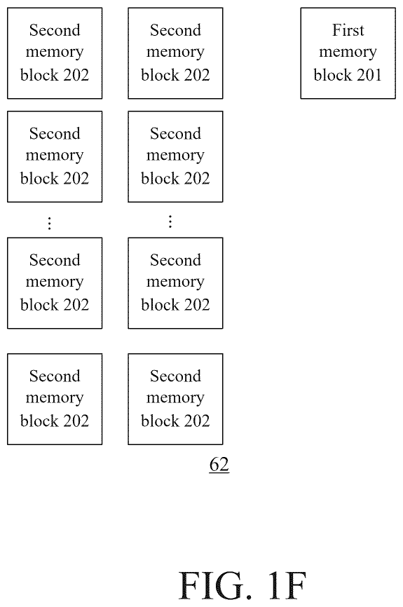

As shown in FIG. 1A, examples of the present disclosure show an example system 10. The example system 10 may comprise a host 20 and a memory system 30. The example system 10 may comprise, but is not limited to, a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatus having a memory device 34 therein. The host 20 may be a processor of an electronic apparatus (e.g., a Central Processing Unit (CPU), or a System on Chip (SoC) (e.g., an Application Processor (AP)).

In an example of the present disclosure, the host 20 may be configured to send or receive data to or from the memory system 30. Here, the memory system 30 may comprise a memory controller 32 and one or more memory devices 34. The memory device 34 may comprise, but is not limited to, a NAND Flash Memory, a Vertical NAND Flash Memory, a NOR Flash Memory, a Dynamic Random Access Memory (DRAM), a Ferroelectric Random Access Memory (FRAM), a Magnetoresistive Random Access Memory (MRAM), a Phase Change Random Access Memory (PCRAM), a Resistive Random Access Memory (RRAM), a Nano Random Access Memory (NRAM), etc.

In an example of the present disclosure, the memory controller 32 may be coupled to the memory device 34 and the host 20, and is configured to control the memory device 34. In an example, the memory controller 32 may be designed for operating in a low duty-cycle environment, such as Secure Digital (SD) cards, Compact Flash (CF) cards, Universal Serial Bus (USB) flash drives, or other media for use in electronic apparatuses, such as personal computers, digital cameras, mobile phones, etc. In some examples, the memory controller 32 may be also designed for operating in a high duty-cycle environment, such as SSDs or embedded Multi-Media Cards (eMMCs) configured as data memories for mobile apparatuses, such as smartphones, tablet computers, laptop computers, etc., and enterprise memory arrays.

Furthermore, the memory controller 32 may manage data in the memory device 34, and communicate with the host. The memory controller 32 may be configured to control read, erase, and program operations of the memory device 34, may further be configured to manage various functions with respect to data stored or to be stored in the memory device 34, comprising, but not limited to, bad-block management, garbage collection, logical-to-physical address conversion, wear leveling, etc., and may further be configured to process Error Checking and Correction (ECC) with respect to the data read from or written to the memory device 34. Furthermore, the memory controller 32 may further perform any other suitable functions as well, e.g., formatting the memory device 34 or communicating with an external apparatus (e.g., the host 20 in FIG. 1) according to a particular communication protocol. In an example, the memory controller 32 may communicate with the external host through at least one of various interface protocols, such as a USB protocol, an MMC protocol, a Peripheral Component Interconnect (PCI) protocol, a PCI-Express (PCI-E) protocol, an Advanced Technology Attachment (ATA) protocol, a serial-ATA protocol, a parallel-ATA protocol, a Small Computer System Interface (SCSI) protocol, an Enhanced Small Disk Interface (ESDI) protocol, an Integrated Development Equipment (IDE) protocol, a Firewire protocol, etc.

In an example of the present disclosure, the memory controller 32 and the one or more memory devices 34 may be integrated into various types of memory apparatuses, e.g., be comprised in the same package (e.g., a Universal Flash Storage (UFS) package or an eMMC package). That is, the memory system 30 may be implemented and packaged into different types of end electronic products. As shown in FIG. 1B, the memory controller 32 and the single memory device 34 may be integrated together to form a memory card 40. The memory card 40 may comprise a Personal Computer Memory Card International Association (PC) card, a CF card, a Smart Media (SM) card, a memory stick, a Multi-Media Card (MMC), Reduced-Size MMC (RS-MMC), MMC micro, an SD card (SD, miniSD, microSD, Secure Digital High Capacity (SDHC)), and UFS, etc. The memory card 40 may further comprise a memory card connector 42 coupling the memory card 40 with a host (e.g., the host 20 in FIG. 1A). In another example shown in FIG. 1C, the memory controller 32 and the plurality of memory devices 34 may be integrated together to form an SSD 50. The SSD 50 may further comprise an SSD connector 52 coupling the SSD 50 with the host (e.g., the host 20 in FIG. 1A). In some examples, at least one of a storage capacity or an operation speed of the SSD 50 is greater than that of the memory card 40.

It is to be noted that the memory involved in an example of the present disclosure may be a semiconductor memory, which is a solid state electronic device manufactured by a semiconductor integrated circuit process that stores data information. In an example, FIG. 1D is a schematic diagram of an example memory device 34 in examples of the present disclosure. As shown in FIG. 1D, the memory device 34 may comprise a memory cell array 62 and a peripheral circuit 64 coupled to the memory cell array 62, etc. Here, the memory cell array may be a NAND flash memory cell array in which memory cells are disposed in a form of an array of NAND memory strings 66 each extending vertically above a substrate. In some examples, each NAND memory string 66 may comprise a plurality of memory cells that are coupled in series and stacked vertically. Each memory cell may maintain a continuous analog value, such as voltage or charge, which depends on the number of electrons trapped within a memory cell region. In addition, the memory cell in the above-mentioned memory cell array 62 may be either a floating gate type memory cell that comprises a floating gate transistor, or a charge trapping type memory cell that comprises a charge trapping transistor.

In an example of the present disclosure, the above-mentioned memory cell may be a Single Level Cell (SLC) that has two possible memory states and thus may store one bit of data. For example, a first memory state “0” may correspond to a first threshold voltage range, and a second memory state “1” may correspond to a second threshold voltage range. In some other examples, each memory cell may be a Multi Level Cell (MLC) that may store more than one bit of data. For example, the MLC may store two bits per cell. Each memory cell may further be a Triple Level Cell (TLC), or each memory cell may further be a Quad Level Cell (QLC). Each MLC may be programmed to a range of possible nominal memory values. In an example, if each MLC stores two bits of data, the MLC may be programmed such that the memory cell is programmed from an erase state to one of three possible program states by writing one of three possible nominal memory values to the memory cell. A fourth nominal memory value may be configured to correspond to the erase state.

In the examples of the present disclosure, the above-mentioned peripheral circuit 64 may be coupled to the memory cell array through a Bit Line (BL), a Word Line (WL), a Source Line, a Source Select Gate (SSG) and a Drain Select Gate (DSG). Here, the peripheral circuit 64 may comprise any suitable analog, digital, and hybrid signal circuits for facilitating relevant operations of the memory cell array by applying and sensing at least one of voltage signals current signals to and from each target memory cell via the bit line, the word line, the source line, the SSG, or the DSG, etc. Furthermore, the peripheral circuit 64 may further comprise various types of peripheral circuits formed using a Metal-Oxide-Semiconductor (MOS) technology. In an example, as shown in FIG. 1E, the peripheral circuit 64 may comprise a Page Buffer (PB)/sense amplifier 71, a column decoder/bit line driver 72, a row decoder/word line driver 73, a voltage generator 74, a control logic unit 75, a register 76, an interface 77, and a data bus 78. In some other examples, the peripheral circuit 64 may further comprise additional peripheral circuits not shown in FIG. 1E.

In some examples, the memory controller may record erase counts of a plurality of memory blocks in the connected memory device. The erase counts are configured to reflect a wear level.

However, for the memory device inside, a wear level of each memory block is not recorded, such that the memory device does not know a stage of life cycle that the memory device is in. In particular, when the memory controller is damaged or fails, the recorded erase counts of the plurality of memory blocks are lost. In this case, the memory device does not know at all the stage of life cycle that the memory device is in.

In addition, the memory device also needs to know the stage of life cycle that the memory device is in to improve the reliability and performance of program and erase operations.

In some examples, an erase count of each memory block may be recorded inside the memory device. However, if the erase count of each memory block is recorded, a large storage capacity is required, and the performance of the memory device is affected.

In order to solve the above problem, examples of the present disclosure provide a memory device. The memory device comprises a memory cell array and a peripheral circuit coupled with the memory cell array. As shown in FIG. 1F, the memory cell array 62 comprises at least one first memory block 201 and a plurality of second memory blocks 202, and part of the plurality of second memory blocks 202 are configured as sampling memory blocks; and the peripheral circuit is configured to:

perform an erase operation on the sampling memory blocks; and

record an erase count of the sampling memory blocks in the at least one first memory block 201.

The memory device in the examples of the present disclosure comprises, but is not limited to, a NAND flash memory, a vertical NAND flash memory, a NOR flash memory, a dynamic random access memory, a ferroelectric random access memory, a magnetic random access memory, a phase change random access memory, a resistive random access memory, a nano random access memory, etc.

In the examples of the present disclosure, a user may perform corresponding read, write, erase, and other operations on the second memory blocks 202. For the first memory block 201, the user may not perform write and erase operations on the first memory block 201, and may perform only a write operation on the first memory block 201, to allow the user to acquire an erase count of a sampling memory block.

During practical use, the memory device needs to be coupled with the memory controller to form the memory system for use together. The memory controller generally has a wear leveling function. The function may uniformly use the plurality of second memory blocks 202 in the memory device, to avoid some second memory blocks 202 from turning into bad blocks due to excessive use. In this way, the plurality of second memory blocks 202 in the memory device approximately undergo balanced erase counts. Therefore, part of the memory blocks may be selected from the plurality of second memory blocks 202 as sampling memory blocks, to represent all second memory blocks 202. In the examples of the present disclosure, by recording the erase counts of sampling memory blocks, instead of recording erase counts of all second memory blocks 202, a space for storing these erase counts may be reduced, that is, a number of first memory blocks 201 is reduced, and a time for recording may be reduced.

In the examples of the present disclosure, part of the second memory blocks 202 may be selected from the plurality of second memory blocks 202 as sampling memory blocks in a manner of random sampling, systematic sampling, etc.

In some examples, the memory cell array comprises a plurality of memory planes, the memory plane comprises a plurality of second memory blocks, and all the sampling memory blocks belong to a same memory plane.

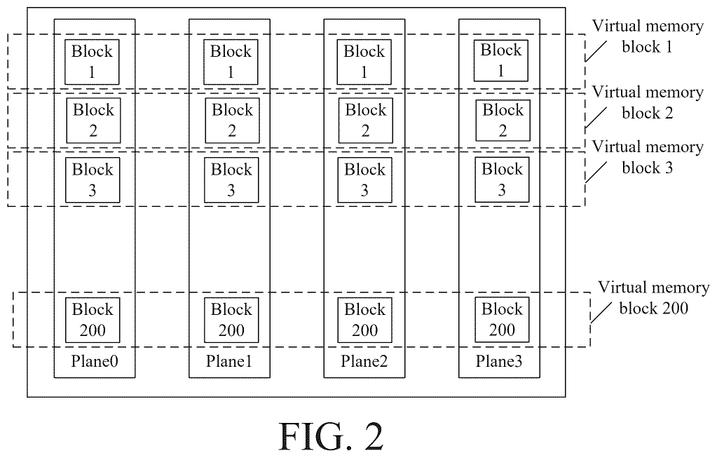

In the examples of the present disclosure, the memory cell array comprises a plurality of memory planes, and the memory planes may be sequentially numbered starting from 0 (for example, Plane0, Plane1, Plane2, . . . ). Different memory planes comprise a same number of second memory blocks, and the second memory blocks may be sequentially numbered starting from 1 (for example, Blcok1, Block2, Block3, . . . ). FIG. 2 shows an example in which the memory cell array comprises four memory planes, and each memory plane comprises 200 second memory blocks. It should be understood that the above-mentioned number of the memory planes, and number of the memory blocks are only an example. This is not limited in the present disclosure. The second memory blocks with a same number in each of the memory planes constitute one virtual block (VB). As shown in FIG. 2, a plurality of Block1 (first of the second memory blocks) in Plane0 to Plane3 constitute a virtual memory block 1, a plurality of Block2 (second of the second memory blocks) in Plane0 to Plane3 constitute a virtual memory block 2, and the like.

In some examples, a virtual memory block may be configured as a unit to perform a Program/Erase (P/E) operation on a plurality of planes, which may reduce the complexity of managing memory blocks. P/E cycles represent an erasable count. Each time program (that is, write)/erase is performed once, one P/E count is counted.

Therefore, for a virtual memory block, any second memory block in the virtual memory block may represent erase counts of all second memory blocks in the virtual memory block.

In some examples, each sampling memory block belongs to a different virtual memory block.

In some examples, all the sampling memory blocks may belong to a same memory plane. For example, part of the second memory blocks may be selected from Plane0 as all sampling memory blocks, or part of the second memory blocks may be selected from Plane1 as all sampling memory blocks.

In some examples, all the sampling memory blocks may belong to different memory planes.

For example, part of the second memory blocks may be selected from Plane0 as part of all the sampling memory blocks, or part of the second memory blocks may be selected from Plane1 as the other part of all the sampling memory blocks.

In some examples, the plurality of second memory blocks in the memory plane are numbered in sequence, and a same number difference exists between adjacent sampling memory blocks.

In some examples, as shown in FIG. 2, each memory plane comprises 200 second memory blocks with numbers from 1 to 200. 10 second memory blocks may be selected from a same memory plane as sampling memory blocks. That is, one second memory block is selected from 20 second memory blocks as a sampling memory block. For example, second memory blocks with numbers of 20, 40, 60, 80, . . . , 200 are selected as sampling memory blocks. For example, second memory blocks with numbers of 20, 40, 60, 80, . . . , 200 in Plane0 are selected as sampling memory blocks.

Second memory blocks with numbers of 20, 40, 60, 80, . . . , 200 may be respectively selected from different memory planes as sampling memory blocks. For example, second memory blocks with numbers of 20, 40, 60, 80, and 100 in Plane0, and second memory blocks with numbers of 120, 140, 160, 180, and 200 in Plane1 are selected as sampling memory blocks.

In the examples of the present disclosure, a manner for selecting sampling memory blocks is not limited. Part of the second memory blocks may be uniformly and discretely selected from the memory cell array as sampling memory blocks in a manner comprising, but not limited to, systematic sampling.

In the examples of the present disclosure, part of the second memory blocks may be selected from a plurality of second memory blocks as sampling memory blocks in a manner of random sampling, systematic sampling, etc., and erase counts of these sampling memory blocks are recorded in at least one first memory block. The erase counts recorded in the first memory block may be read to clearly know a stage of life cycle that a memory device is in, and subsequently the reliability and performance of program and erase operations may be improved according to different wear levels. For example, if the memory device is in an end stage of life cycle, data that does not require frequent update may be stored in the memory device as much as possible. If the memory device is in an early stage of life cycle, data that requires frequent update may be stored in the memory device as much as possible. In addition, because an erase count of a sampling memory block is recorded inside the memory device in this example, even if a memory controller is damaged or fails, the faulty memory controller may be replaced with a new memory controller. An external device may still acquire an erase count of a sampling memory block stored in the memory device through the new memory controller. As such, the overall validity of the memory system is improved.

In some examples, the peripheral circuit is configured to: perform an erase operation on a selected second memory block;
record, based on the selected second memory block belonging to the sampling memory block, an erase count of the selected second memory block in the first memory block; and
not recording, based on the selected second memory block belonging to a non-sampling memory block, an erase count of the selected second memory block.

In the examples of the present disclosure, an erase operation may be performed on any second memory block. However, erase counts of only second memory blocks belonging to sampling memory blocks are recorded. Therefore, after an erase operation is performed on a selected second memory block, address information of the selected second memory block may be compared with address information of the sampling memory blocks, and based on a comparison result, whether the selected second memory block belongs to a sampling memory block is determined.

In some examples, the at least one first memory block comprises a plurality of physical page groups, and each of the physical page groups correspondingly stores a plurality of erase counts of one sampling memory block. The memory device comprises a register. The peripheral circuit is configured to:
in response to the erase operation performed on the sampling memory block being the first erase operation in a current power supply cycle of the memory device, search a physical page group corresponding to the sampling memory block for a physical page recording the largest erase count of the plurality of erase counts of the sampling memory block; and
store address information of the physical page recording the largest erase count of the plurality of erase counts of the sampling memory block in a first region of the register.

For different memory cells, erasable counts of different memory cells are different. Generally, an erasable count of an SLC is greater than an erasable count of an MLC, the erasable count of the MLC is greater than an erasable count of a TLC, and the erasable count of the TLC is greater than an erasable count of a QLC.

In some examples, an erase count of each sampling memory block in one power supply cycle may be counted by using a plurality of counters. One counter may correspond to one sampling memory block for counting. When the power supply cycle ends (that is, at a power failure), the plurality of counters are reset to return to an initial value 0.

The memory device provided by the examples of the present disclosure comprises a register. A first region of the register is configured for storing address information of the physical page recording the largest erase count of the plurality of erase counts of the sampling memory block. Information stored in the register is volatile. That is, after a previous power supply cycle ends, address information stored in the register is reset. Therefore, after an erase operation is performed on a sampling memory block, whether the erase operation performed on the sampling memory block is the first erase operation in the current power supply cycle needs to be determined.

The register in the examples of the present disclosure may be a register 76 in FIG. 1E, or may also be a register additionally disposed in the peripheral circuit.

In some examples, a size of the first region of the register is equal to a number of sampling memory blocks*a size of address information of each physical page. For example, the size of the address information of each physical page may be 11 bits. The first region may be divided into a plurality of first sub-regions. A number of the first sub-regions is equal to the number of sampling memory blocks, and a size of each first sub-region is equal to the size of the address information of each physical page. Each first sub-region is configured for storing corresponding address information. It should be understood that the above-mentioned size of the address information is only an example, and the present disclosure is not limited thereto.

In some examples, the peripheral circuit is configured to:
determine, based on identifier information stored in a second region of the register, whether the erase operation performed on the sampling memory block is the first erase operation in the current power supply cycle.

In the examples of the present disclosure, the identifier information indicating whether the erase operation is the first erase operation in the current power supply cycle is stored in the second region of the register. In some examples, a size of the identifier information may be 1 bit. A value of one bit may be “0” or “1”. For example, the identifier information being “1” indicates that the erase operation is not the first erase operation of the current power supply cycle, and the identifier information being “0” indicates that the erase operation is the first erase operation of the current power supply cycle.

After a previous power supply cycle ends, the identifier information is reset to “0”. After it is determined that the erase operation is the first erase operation of the current power supply cycle, the identifier information is set to “1”. In addition, before a current power supply cycle ends, the identifier information remains “1”.

The identifier information being “0” indicates that the erase operation is the first erase operation of the current power supply cycle. In this case, the address information in the first region of the register is reset. Therefore, it is necessary to search the physical page group corresponding to the sampling memory block for the physical page recording the largest erase count of the plurality of erase counts of the sampling memory block. Subsequently, a total erase count of the sampling memory block may continue to be recorded in the physical page recording the largest erase count of the plurality of erase counts of the sampling memory block or a physical page following the physical page recording the largest erase count.

In some examples, the at least one first memory block comprises a plurality of physical page groups, and each of the physical page groups correspondingly stores a plurality of erase counts of one sampling memory block. The memory device comprises a register. The peripheral circuit is configured to:

in response to the erase operation performed on the sampling memory block being an Nth erase operation in a current power supply cycle of the memory device, read address information of a physical page recording the largest erase count of the plurality of erase counts of the sampling memory block that is stored in a first region of the register, wherein N is an integer greater than or equal to 2.

The identifier information being “1” indicates that the erase operation is the Nth erase operation rather than the first erase operation in the current power supply cycle. The address information of the physical page recording the largest erase count of the plurality of erase counts of the sampling memory block stored in the first region of the register is read, and the total erase count of the sampling memory block may continue to be recorded in the physical page recording the largest erase count of the plurality of erase counts of the sampling memory block or a physical page following same.

The total erase count refers to entire erase counts performed on the sampling memory block in the current power supply cycle and before the current power supply cycle.

The largest erase count refers to the largest erase count of the plurality of erase counts. The plurality of erase counts here all used to be total erase counts.

In some examples, if the physical page recording the largest erase count of the plurality of erase counts of the sampling memory block is not fully written, the total erase count of the sampling memory block may continue to be recorded in the physical page.

In some examples, if the physical page recording the largest erase count of the plurality of erase counts of the sampling memory block has been fully written, the total erase count of the sampling memory block may continue to be recorded in physical page following the physical page.

In some examples, the peripheral circuit is configured to search the physical page group corresponding to the sampling memory block for the physical page recording the largest erase count of the plurality of erase counts of the sampling memory block by using dichotomy.

In the examples of the present disclosure, the physical page group corresponding to the sampling memory block is searched for the physical page recording the largest erase count of the plurality of erase counts of the sampling memory block by using dichotomy, such that search efficiency may be effectively improved. The physical page group corresponding to the sampling memory block comprises M pages, and a maximum search count obtained by using dichotomy is [log₂ (M)]+1. For example, M is 230, and the maximum search count obtained by using dichotomy is [log₂ (M)]+1=11. Here, [ ] is a symbol of rounding down.

In some examples, the peripheral circuit is configured to search the physical page group corresponding to the sampling memory block for the physical page recording the largest erase count of the plurality of erase counts of the sampling memory block by using sequential search.

In some examples, the physical page group corresponding to the sampling memory block comprises K+1 physical pages consecutively numbered from M to M+K, wherein M and K are positive integers. The peripheral circuit is configured to:
determine, according to the address information of the physical page recording the largest erase count of the plurality of erase counts of the sampling memory block in the first region of the register, whether the physical page recording the largest erase count of the plurality of erase counts of the sampling memory block is the last physical page in the physical page group corresponding to the sampling memory block;
if the address information indicates that the physical page recording the largest erase count of the plurality of erase counts of the sampling memory block is the physical page with the number of M+K, not recording total erase counts of the sampling memory block in the current power supply cycle and before the current power supply cycle; and
if the address information indicates that the physical page recording the largest erase count of the plurality of erase counts of the sampling memory block is the physical page with any number of M to M+K−1, record an erase count of the sampling memory block in the current power supply cycle.

In the examples of the present disclosure, a preset erasable count (that is, a preset total erase count) is set, and only an erase count within the preset erasable count may be recorded. The reason is that if an actual erase count of the sampling memory block exceeds the preset erasable count, the sampling memory block has reached the end of life cycle, and it is of little significance to continue to record the erase count of the sampling memory block. In the examples of the present disclosure, K+1 physical pages consecutively numbered from M to M+K are provided for each sampling memory block to record preset erasable count. That is, the K+1 physical pages may just record all the preset erasable counts, and no physical page is wasted.

Therefore, in the examples of the present disclosure, after the address information of the physical page recording the largest erase count of the plurality of erase counts of the sampling memory block in the first region of the register is read, it is further necessary to continue to determine whether the physical page recording the largest erase count of the plurality of erase counts of the sampling memory block is the last physical page in the physical page group corresponding to the sampling memory block. That is, whether the physical page group is fully written is determined. If the physical page group is fully written, that is, the preset erasable count is reached, even if subsequently an erase operation is further performed on the sampling memory block, the erase count of the sampling memory block is no longer recorded. If the physical page group is not fully written, the erase count of the sampling memory block in the current power supply cycle is recorded by using a counter. It is to be noted that, the recording here refers to temporary recording in the counter, and the erase count is not necessarily synchronously recorded in the physical page group corresponding to the sampling memory block. In some examples, when a value recorded in the counter reaches a particular condition, the erase count is synchronously recorded in the physical page group corresponding to the sampling memory block.

The erase count in the current power supply cycle in the examples of the present disclosure is not related to an erase count in a previous power supply cycle. A sum of the erase count before the current power supply cycle and the erase count in the current power supply cycle is equal to the total erase count.

In some examples, the peripheral circuit is configured to:
every time when the erase count of the sampling memory block in the current power supply cycle reaches a multiple of a preset erase count, record, in the first memory block, a total erase count of the sampling memory block after the erase operation is performed on the sampling memory block in the current power supply cycle; and
write address information of a physical page recording the total erase count of the sampling memory block in the first region of the register.

In some examples, the preset erase count may be a fixed value. For example, the preset erase count is an integer greater than or equal to 1. An example in which the preset erase count is fixedly 3 is illustrated below.

When the erase count of the sampling memory block in the current power supply cycle recorded in the counter reaches a multiple of the preset erase count, for example, is 3, 6, 9, . . . , the total erase count of the sampling memory block after the erase operation is performed on the sampling memory block in the current power supply cycle is recorded in the first memory block, and the address information of the physical page recording the total erase count of the sampling memory block is written in the first region of the register.

In the examples of the present disclosure, the total erase count of the sampling memory block may be found by reading the address information in the first region of the register, such that a stage of life cycle that the memory device is in may be known.

In some examples, the preset erase count may be a non-fixed value.

In some examples, if the total erase count of the sampling memory block is less than a first preset value, the preset erase count is a first value;
if the total erase count of the sampling memory block is greater than or equal to the first preset value and less than a second preset value, the preset erase count is a second value; and
if the total erase count of the sampling memory block is greater than or equal to the second preset value and less than a third preset value, the preset erase count is a third value.

In some examples, the third value is greater than the second value, and the second value is greater than the first value.

If a value of the preset erase count is excessively large, the recording of the erase count is not precise enough. If the value of the preset erase count is excessively small, the recording of the erase count is excessively frequent, consuming a large program count. Here, the programming refers to recording an erase count in the first memory block.

In the examples of the present disclosure, in an early stage of life cycle of the memory device, the recording of the erase count may be relatively precise, and therefore the first value may be relatively small. In a middle stage of life cycle of the memory device, the recording of the erase count may be less precise, and therefore the second value may be greater than the first value. In an end stage of life cycle of the memory device, the recording of the erase count may be relatively rough, and therefore the third value may be greater than the second value.

In the examples of the present disclosure, an example in which a memory cell in the second memory block is a TLC and preset erasable count is 2996 is illustrated.

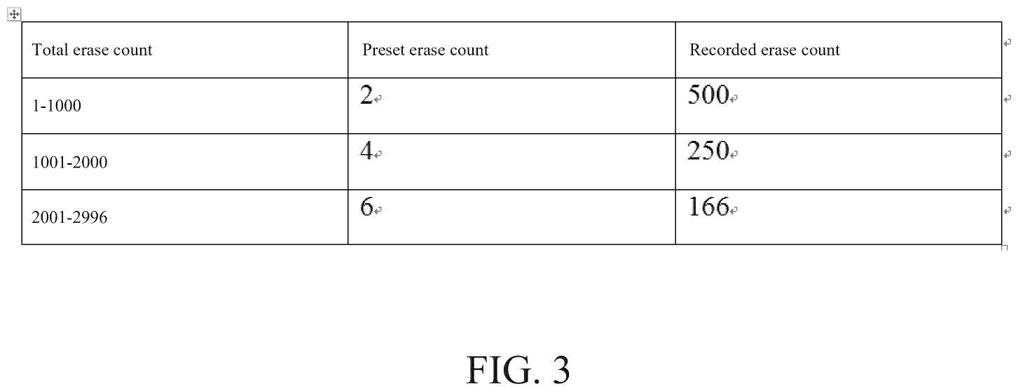

As shown in FIG. 3, when the total erase count of the sampling memory block is between 1 and 1000, the preset erase count is the first value, and the first value is equal to 2. That is, the second erase, the fourth erase, . . . , and the like are recorded. When the 1000th erase is recorded, an erase count of 500 is recorded in total.

When the total erase count of the sampling memory block is between 1000 and 2000, the preset erase count is the second value, and the second value is equal to 4. That is, the 1004th erase, the 1008th erase, . . . , and the like are recorded. When the 2000th erase is recorded, an erase count of 250 is recorded in total.

When the total erase count of the sampling memory block is between 2000 and 3000, the preset erase count is the third value, and the third value is equal to 6. That is, the 2006th erase, the 2012th erase, . . . , and the like are recorded. When the 2996th erase is recorded, an erase count of 166 is recorded in total.

In summary, an erase count of 500+250+166=916 is recorded in total. If a second memory cell is an SLC and the NOP of the second memory cell is 4, a total of 229 physical pages are required to record an erase count of 916, that is, one physical page group comprises 229 physical pages.

If 10 memory blocks of the plurality of second memory blocks are configured as sampling memory blocks, a total of 2290 physical pages are required to record an erase count for the 10 sampling memory blocks. If a number of physical pages in the first memory block is greater than or equal to 2290, in this case, a entire erase count of the 10 sampling memory blocks may be recorded by providing one first memory block. If the number of physical pages in the first memory block is greater than 1145 and less than 2290, in this case, the entire erase count of the 10 sampling memory blocks may be recorded by providing two first memory blocks. In the examples of the present disclosure, a number of first memory blocks may be determined according to a number of physical pages required for all sampling memory blocks and a number of physical pages in each first memory block.

In some examples, the preset erase count may be determined according to the number of the first memory blocks and the number of physical pages of the first memory block, to ensure that all preset erasable counts may be recorded.

It is to be noted that, for example, when a total erase count of the sampling memory block is between 1 and 1000, in a current power supply cycle, for example, the sampling memory block encounters a power failure after one erase, in this case, the total erase count of the sampling memory block is not increased. Therefore, there is a difference between the total erase count of the sampling memory block and an actual entire erase count of the sampling memory block, and a recorded total erase count of the sampling memory block is less than the actual entire erase count of the sampling memory block.

It should be understood that the above-mentioned first value, second value, and third value are only an example. The present disclosure is not limited thereto. The values may be taken according to actual requirements of the user.

In some examples, the second memory block comprises a plurality of first memory cells, and each of the first memory cells may store at least one bit of data. The first memory block comprises a plurality of second memory cells, and each of the second memory cells may store one bit of data.

In some examples, a mode of the memory device may be a single mode, for example, an SLC mode. That is, the first memory cell and the second memory cell are both SLCs. The characteristics of the SLC mode are faster read/write performance and stricter reliability quality.

In some examples, the mode of the memory device may be a hybrid mode: “XLC mode+SLC mode”. XLC comprises, but is not limited to, an MLC, a TLC, and a QLC, etc. The two modes may be cooperatively used under the control of a controller, such that the advantage of high-speed read/write performance of the SLC mode may be obtained, and a high storage capacity of the XLC mode that is many times that of the SLC mode may be obtained.

In the order of the SLC mode, the MLC mode, the TLC mode, and the QLC mode, the storage capacity increases, but reliability quality such as service life, data retention capability, etc. sequentially decreases.

The reason that the second memory cell may be an SLC further lies in that a number of programs (NOP) of the SLC is relatively high, such that a use number of first memory blocks may be reduced. The number of programs here represents an upper limit of a number of partial programs of each physical page. For example, NOP=4 represents that data may be written in each physical page at most four times. Generally, an NOP of an SLC is 4-8, and NOPs of an MLC and a TLC are 1.

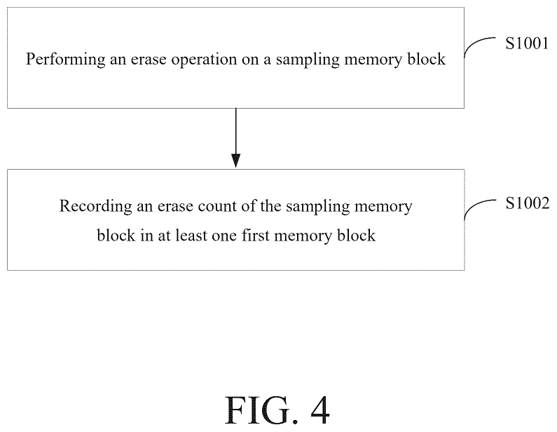

Examples of the present disclosure further provide an operation method of a memory device. As shown in FIG. 4, the method comprises the following operations.

Operation S1001: Performing an erase operation on a sampling memory block.

Operation S1002: Recording an erase count of the sampling memory block in at least one first memory block.

In the examples of the present disclosure, part of the second memory blocks may be selected from a plurality of second memory blocks as sampling memory blocks in a manner of random sampling, systematic sampling, etc., and erase counts of these sampling memory blocks are recorded in at least one first memory block. The erase counts recorded in the first memory block may be read to clearly know a stage of life cycle that a memory device is in, and subsequently the reliability and performance of program and erase operations may be improved according to different wear levels. For example, if the memory device is in an end stage of life cycle, data that does not require frequent update may be stored in the memory device as much as possible. If the memory device is in an early stage of life cycle, data that requires frequent update may be stored in the memory device as much as possible. In addition, because an erase count of a sampling memory block is recorded inside the memory device in this example, even if a memory controller is damaged or fails, the faulty memory controller may be replaced with a new memory controller. An external device may still acquire an erase count of a sampling memory block stored in the memory device through the new memory controller. As such, the overall validity of the memory system is improved.

In some examples, the method further comprises:
performing an erase operation on a selected second memory block;
recording, based on the selected second memory block belonging to the sampling memory block, an erase count of the selected second memory block in the first memory block; and
not recording, based on the selected second memory block not belonging to the sampling memory block, an erase count of the selected second memory block.

In some examples, the method further comprises:
in response to the erase operation performed on the sampling memory block being the first erase operation in a current power supply cycle of the memory device, searching a physical page group corresponding to the sampling memory block for a physical page recording the largest erase count of the plurality of erase counts of the sampling memory block; and
storing address information of the physical page recording the largest erase count of the plurality of erase counts of the sampling memory block in a first region of a register.

In some examples, the searching the physical page group corresponding to the sampling memory block for the physical page recording the largest erase count of the sampling memory block comprises:
searching the physical page group corresponding to the sampling memory block for the physical page recording the largest erase count of the plurality of erase counts of the sampling memory block by using dichotomy.

In some examples, the method further comprises:
in response to the erase operation performed on the sampling memory block being an Nth erase operation in a current power supply cycle of the memory device, reading address information of a physical page recording the largest erase count of the plurality of erase counts of the sampling memory block that is stored in a first region of a register, wherein N is an integer greater than or equal to 2.

In some examples, the method further comprises:
determining, based on identifier information stored in a second region of the register, whether the erase operation performed on the sampling memory block is the first erase operation in the current power supply cycle.

In some examples, the physical page group corresponding to the sampling memory block comprises K+1 physical pages consecutively numbered from M to M+K, wherein M and K are positive integers; and the method further comprises:
determining, according to the address information of the physical page recording the largest erase count of the plurality of erase counts of the sampling memory block in the first region of the register, whether the physical page recording the largest erase count of the plurality of erase counts of the sampling memory block is the last physical page in the physical page group corresponding to the sampling memory block;
if the address information indicates that the physical page recording the largest erase count of the plurality of erase counts of the sampling memory block is the physical page with the number of M+K, not recording an erase count of the sampling memory block in the current power supply cycle; and
if the address information indicates that the physical page recording the largest erase count of the plurality of erase counts of the sampling memory block is the physical page with any number of M to M+K−1, recording an erase count of the sampling memory block in the current power supply cycle.

In some examples, the method further comprises:
every time when the erase count of the sampling memory block in the current power supply cycle reaches a multiple of a preset erase count, recording, in the first memory block, a total erase count of the sampling memory block after the erase operation is performed on the sampling memory block in the current power supply cycle; and
writing address information of a physical page recording the total erase count of the sampling memory block in the first region of the register.

In some examples, if the total erase count of the sampling memory block is less than a first preset value, the preset erase count is a first value;
if the total erase count of the sampling memory block is greater than or equal to the first preset value and less than a second preset value, the preset erase count is a second value; and
if the total erase count of the sampling memory block is greater than or equal to the second preset value and less than a third preset value, the preset erase count is a third value.

In some examples, the third value is greater than the second value, and the second value is greater than the first value.

In some examples, the memory cell array comprises a plurality of memory planes, the memory plane comprises a plurality of second memory blocks, and all the sampling memory blocks belong to a same memory plane.

In some examples, the plurality of second memory blocks in the memory plane are numbered in sequence, and a same number difference exists between adjacent sampling memory blocks.

In some examples, the second memory block comprises a plurality of first memory cells, and each of the first memory cells may store at least one bit of data. The first memory block comprises a plurality of second memory cells, and each of the second memory cells may store one bit of data.

An example aspect of the method in the above example is described in detail in examples of a product corresponding to the method, and is no longer set forth in detail here.

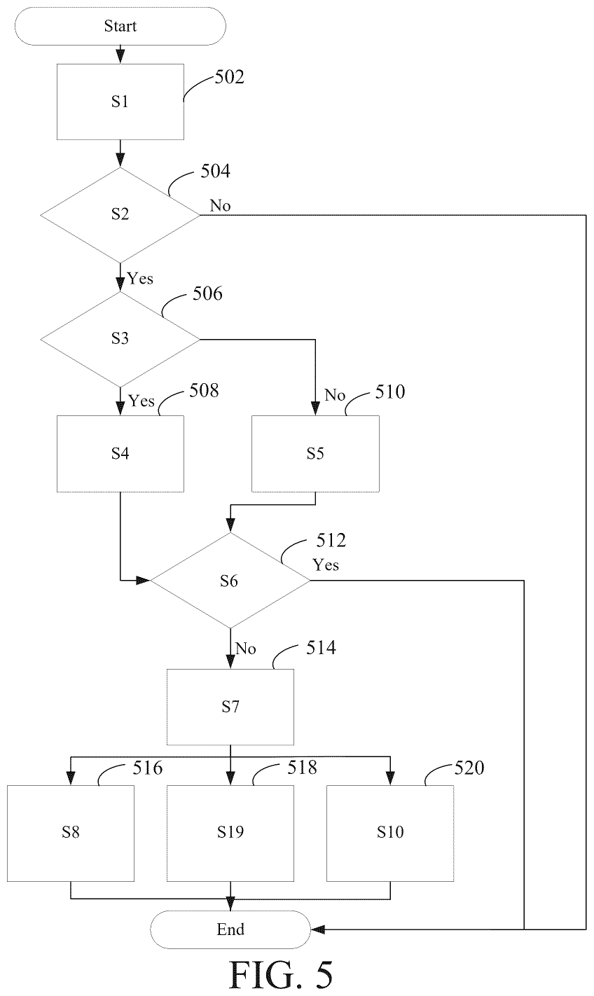

The present disclosure further provides the following example, as shown in FIG. 5.

Operation S1 (block 502) is first performed: performing an erase operation on a selected second memory block.

Operation S2 (block 504) is then performed: determining whether the selected second memory block belongs to a sampling memory block, and if the selected second memory block belongs to a non-sampling memory block, not recording an erase count of the selected second memory block, that is, ending a current procedure.

If the selected second memory block belongs to the sampling memory block, Operation S3 (block 506) continues to be performed: reading identifier information stored in a second region of a register, and determining whether the erase operation performed on the sampling memory block is the first erase operation in a current power supply cycle.

If the erase operation performed on the sampling memory block is the first erase operation in the current power supply cycle, Operation S4 (block 508) continues to be performed: searching a physical page group corresponding to the sampling memory block for a physical page recording the largest erase count of a plurality of erase counts of the sampling memory block by using dichotomy, and storing address information of the physical page recording the largest erase count of the plurality of erase counts of the sampling memory block in a first region of the register.

If the erase operation performed on the sampling memory block is not the first erase operation in the current power supply cycle, Operation S5 (block 510) continues to be performed: reading address information of a physical page recording the largest erase count of a plurality of erase counts of the sampling memory block that is stored in a first region of the register.

Operation S6 (block 512) continues to be performed: determining whether the physical page recording the largest erase count of the plurality of erase counts of the sampling memory block is the last physical page in the physical page group corresponding to the sampling memory block; and

if the physical page recording the largest erase count of the plurality of erase counts of the sampling memory block is the last physical page in the physical page group corresponding to the sampling memory block, not recording total erase counts of the sampling memory block in the current power supply cycle and before the current power supply cycle, that is, ending the current procedure.

If the physical page recording the largest erase count of the plurality of erase counts of the sampling memory block is not the last physical page in the physical page group corresponding to the sampling memory block, Operation S7 (block 514) continues to be performed: recording an erase count of the sampling memory block in the current power supply cycle.

Operation S8 (block 516) continues to be performed: if the total erase count of the sampling memory block is between 1 and 1000 and every time the erase count of the sampling memory block in the current power supply cycle reaches a multiple of 2, recording, in a first memory block, the total erase count of the sampling memory block after the erase operation is performed on the sampling memory block in the current power supply cycle, and updating address information recording the total erase count in the register.

Alternatively, Operation S9 (block 518) continues to be performed: if the total erase count of the sampling memory block is between 1001 and 2000 and every time the erase count of the sampling memory block in the current power supply cycle reaches a multiple of 4, recording, in a first memory block, the total erase count of the sampling memory block after the erase operation is performed on the sampling memory block in the current power supply cycle, and updating address information recording the total erase count in the register.

Alternatively, Operation S10 (block 520) continues to be performed: if the total erase count of the sampling memory block is between 2001 and 2996 and every time the erase count of the sampling memory block in the current power supply cycle reaches a multiple of 6, recording in a first memory block, the total erase count of the sampling memory block after the erase operation is performed on the sampling memory block in the current power supply cycle, and updating address information recording the total erase count in the register.

Finally, the current procedure is ended.

Examples of the present disclosure further provide a memory system, comprising: the memory device of any one of the above examples; and a memory controller having a wear leveling function which is coupled with the memory device.

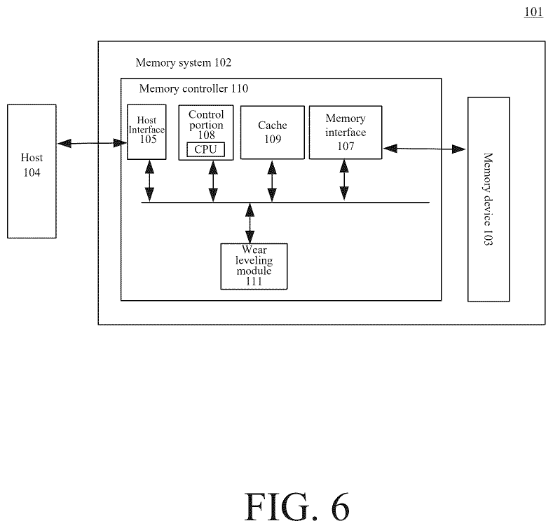

FIG. 6 is a schematic structural diagram of a memory system 101. The memory system 101 comprises a memory controller 102 and a memory device 103. The memory controller 102 is configured to control the memory device 103 to perform read and write operations. Here, the memory controller 102 may be coupled the memory device 103 in any appropriate manner. The memory controller 102 comprises a control portion (CPU) 108, a cache 109, a host interface 105, a memory interface 107, and a wear leveling module 111. In the examples of the present disclosure, the memory device 103 may be a semiconductor memory storing data in a non-volatile manner, such as, a NAND memory. The memory system 101 is connected with a host 104. The host interface 105 outputs a command and valid data (write data), etc. received from the host 104 to the internal bus 110, and sends the valid data (read data) read from the memory device 103, and response from the control portion 108, etc. to the host 104.

The memory interface 107 controls processing of writing and reading the data, etc. to and from the memory device 103 based on an instruction of the control portion 108. The control portion 108 overall controls the memory system 101, and is, for example, a central processing unit (CPU), a micro-processing unit (MPU), etc. The control portion 108 performs control according to a command in the case where the control portion 108 receives the command from the host 104 via the host interface 105. For example, the control portion 108 instructs the memory interface 107 to write the data to the memory device 103 according to a command from the host 104. Furthermore, the control portion 108 instructs the memory interface 107 to read the data from the memory device 103 according to a command from the host 104.

The cache 109 temporarily saves the data received from the host 104 before storing the data to the memory device 103, and temporarily saves the data read from the memory device 103 before sending the data to the host 104.

The flash memory has a service life. That is, a memory block of the flash memory has a limited number of erases and writes. If the number of erases and writes of one memory block exceeds a particular value, the memory block becomes not that reliable, or even becomes a usable bad block. The wear leveling module 111 may avoid part of the memory blocks from being frequently erased and written, such that the erase and write value of each memory block is kept relatively equalized, to extend the service life of overall chips.

In some examples, the memory system comprises, but is not limited to, a memory card or a solid state drive.

It is to be understood that “one example” and “an example” mentioned in the whole specification mean that specific features, structures or characteristics related to the example is comprised in at least one example of the present disclosure. Therefore, “in one example” or “in an example” appearing at any place of the whole specification does not always refer to the same example. In addition, these specific features, structures or characteristics may be combined in one or more examples in any proper manner. It is to be understood that, in various examples of the present disclosure, the sequence number of each process does not mean the sequence of execution. The execution sequence of each process should be determined by its functions and internal logic, which should not constitute any limitation on the example process of the examples of the present disclosure. The serial numbers of above examples of the present disclosure are merely for description, and do not represent the superiority or inferiority of the examples.

It is to be noted that term “contain”, and “comprise” or any other variant thereof is intended to cover nonexclusive inclusions herein, such that a process, method, object or apparatus comprising a series of components not only comprises those components but also comprises other components which are not clearly listed or further comprises components intrinsic to the process, the method, the object or the apparatus. In the case of no more limitations, a component defined by the statement “comprising a/an . . . ” does not exclude the existence of another identical component in a process, method, object or apparatus comprising the component.

In view of this, examples of the present disclosure provide a memory device, an operation method of same, and a memory system.

In a first aspect, examples of the present disclosure provide a memory device. The memory device comprises a memory cell array and a peripheral circuit coupled with the memory cell array; the memory cell array comprises at least one first memory block and a plurality of second memory blocks, and part of the plurality of second memory blocks are configured as sampling memory blocks; and the peripheral circuit is configured to: perform an erase operation on the sampling memory block; and record an erase count of the sampling memory block in the at least one first memory block.

In a second aspect, examples of the present disclosure further provide an operation method of a memory device. The method comprises: performing an erase operation on a sampling memory block; and recording an erase count of the sampling memory block in at least one first memory block.

In a third aspect, examples of the present disclosure further provide a memory system, comprising: the memory device of any one of the above examples; and a memory controller having a wear leveling function coupled with the memory device.

In the examples of the present disclosure, part of the second memory blocks may be selected from a plurality of second memory blocks as sampling memory blocks in a manner of random sampling, systematic sampling, etc., and erase counts of these sampling memory blocks are recorded in at least one first memory block. The erase counts recorded in the first memory block may be read to clearly know a stage of life cycle that a memory device is in, and subsequently the reliability and performance of program and erase operations can be improved according to different wear levels. For example, if the memory device is in an end stage of life cycle, data that does not require frequent update may be stored in the memory device as much as possible. If the memory device is in an early stage of life cycle, data that requires frequent update may be stored in the memory device as much as possible. In addition, because an erase count of a sampling memory block is recorded inside the memory device in this example, even if a memory controller is damaged or fails, the faulty memory controller may be replaced with a new memory controller. An external device may still acquire an erase count of a sampling memory block stored in the memory device through the new memory controller. As such, the overall validity of the memory system is improved.

The above descriptions are merely examples of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A memory device, comprising:
a memory cell array, including:
at least one first memory block; and
a plurality of second memory blocks, wherein part of the plurality of second memory blocks are configured as sampling memory blocks; and
a peripheral circuit coupled with the memory cell array and configured to:
perform an erase operation on the sampling memory blocks; and
record an erase count of the sampling memory blocks in the at least one first memory block.

2. The memory device of claim 1, wherein the peripheral circuit is configured to:
perform an erase operation on a selected second memory block; and
record, based on the selected second memory block belonging to the sampling memory blocks, an erase count of the selected second memory block in the at least one first memory block.

3. The memory device of claim 1, wherein the at least one first memory block includes physical page groups, and each of the physical page groups correspondingly stores a plurality of erase counts of one sampling memory block; the memory device includes a register; and the peripheral circuit is configured to:
in response to the erase operation performed on the sampling memory block being a first erase operation in a current power supply cycle of the memory device, search a physical page group corresponding to the sampling memory block for a physical page recording the largest erase count of the plurality of erase counts of the sampling memory block; and
store address information of the physical page recording the largest erase count of the plurality of erase counts of the sampling memory block in a first region of the register.

4. The memory device of claim 3, wherein the peripheral circuit is configured to: search physical page groups corresponding to the sampling memory block for the physical page recording the largest erase count of the plurality of erase counts of the sampling memory block by using dichotomy.

5. The memory device of claim 1, wherein the at least one first memory block includes a plurality of physical page groups, and each of the physical page groups correspondingly stores a plurality of erase counts of one sampling memory block; the memory device includes a register; and the peripheral circuit is configured to:
in response to the erase operation performed on the sampling memory block being an Nth erase operation in a current power supply cycle of the memory device, read address information of a physical page recording the largest erase count of the plurality of erase counts of the sampling memory block that is stored in a first region of the register, wherein N is an integer greater than or equal to 2.

6. The memory device of claim 3, wherein the peripheral circuit is configured to:
determine, based on identifier information stored in a second region of the register, whether the erase operation performed on the sampling memory block is the first erase operation in the current power supply cycle.

7. The memory device of claim 3, wherein the physical page group corresponding to the sampling memory block includes K+1 physical pages consecutively numbered from M to M+K, wherein M and K are positive integers; and the peripheral circuit is configured to:
determine, according to the address information of the physical page recording the largest erase count of the plurality of erase counts of the sampling memory block in the first region of the register, whether the physical page recording the largest erase count of the plurality of erase counts of the sampling memory block is the last physical page in the physical page group corresponding to the sampling memory block;
if the address information indicates that the physical page recording the largest erase count of the plurality of erase counts of the sampling memory block is the physical page with the number of M+K, not recording total erase counts of the sampling memory block in the current power supply cycle and before the current power supply cycle; and
if the address information indicates that the physical page recording the largest erase count of the plurality of erase counts of the sampling memory block is the physical page with any number of M to M+K−1, record an erase count of the sampling memory block in the current power supply cycle.

8. The memory device of claim 7, wherein the peripheral circuit is configured to:
every time when the erase count of the sampling memory block in the current power supply cycle reaches a multiple of a preset erase count, record, in the first memory block, a total erase count of the sampling memory block after the erase operation is performed on the sampling memory block in the current power supply cycle; and
write address information of a physical page recording the total erase count of the sampling memory block in the first region of the register.

9. The memory device of claim 8, wherein
if the total erase count of the sampling memory block is less than a first preset value, the preset erase count is a first value;
if the total erase count of the sampling memory block is greater than or equal to the first preset value and less than a second preset value, the preset erase count is a second value; and
if the total erase count of the sampling memory block is greater than or equal to the second preset value and less than a third preset value, the preset erase count is a third value.

10. The memory device of claim 9, wherein the third value is greater than the second value, and the second value is greater than the first value.

11. The memory device of claim 1, wherein the memory cell array includes a plurality of memory planes, the memory plane includes a plurality of second memory blocks, and all the sampling memory blocks belong to a same memory plane.

12. The memory device of claim 11, wherein the plurality of second memory blocks in the memory plane are numbered in sequence, and a same number difference exists between adjacent sampling memory blocks.

13. The memory device of claim 1, wherein the second memory block includes first memory cells, and each of the first memory cells can store at least one bit of data; and the first memory block includes second memory cells, and each of the second memory cells can store one bit of data.

14. An operation method of a memory device, comprising:
performing an erase operation on a sampling memory block; and
recording an erase count of the sampling memory block in at least one first memory block.

15. The operation method of claim 14, further including:
performing an erase operation on a selected second memory block; and
recording, based on the selected second memory block belonging to the sampling memory block, an erase count of the selected second memory block in the at least one first memory block.

16. The operation method of claim 14, further including:
in response to the erase operation performed on the sampling memory block being a first erase operation in a current power supply cycle of the memory device, searching a physical page group corresponding to the sampling memory block for a physical page recording the largest erase count of a plurality of erase counts of the sampling memory block; and
storing address information of the physical page recording the largest erase count of the plurality of erase counts of the sampling memory block in a first region of a register.

17. The operation method of claim 16, wherein the searching the physical page group corresponding to the sampling memory block for the physical page recording the largest erase count of the sampling memory block includes:
searching the physical page group corresponding to the sampling memory block for the physical page recording the largest erase count of the plurality of erase counts of the sampling memory block by using dichotomy.

18. The operation method of claim 14, further including:
in response to the erase operation performed on the sampling memory block being an Nth erase operation in a current power supply cycle of the memory device, reading address information of a physical page recording the largest erase count of a plurality of erase counts of the sampling memory block that is stored in a first region of a register, wherein N is an integer greater than or equal to 2.

19. The operation method of claim 16, further including:
determining, based on identifier information stored in a second region of the register, whether the erase operation performed on the sampling memory block is the first erase operation in the current power supply cycle.

20. A memory system, comprising:
a memory device, including:
a memory cell array, including:
at least one first memory block; and
a plurality of second memory blocks, wherein part of the plurality of second memory blocks are configured as sampling memory blocks; and
a peripheral circuit coupled with the memory cell array and configured to:
perform an erase operation on the sampling memory blocks; and
record an erase count of the sampling memory blocks in the at least one first memory block; and
a memory controller having a wear leveling function and coupled with the memory device.
